(19) United States
(12) Patent Application Publication
(10) Pub. No.: US 2013/0200499 A1
(43) Pub. Date: Aug. 8, 2013

(54) SEMICONDUCTOR DEVICE

(71) Applicant: Inergy Technology Inc., Hsinchu County (TW)

(72) Inventors: Chorng-Wei Liaw, Hsinchu County (TW); Ming-Jang Lin, Hsinchu City (TW); Wen-Yu Fu, Hsinchu County (TW); Li-Zheng Lin, Taipei City (TW)

(73) Assignee: INERGY TECHNOLOGY INC., Hsinchu County (TW)

(21) Appl. No.: 13/757,864

(22) Filed: Feb. 4, 2013

Related U.S. Application Data
(60) Provisional application No. 61/595,007, filed on Feb. 3, 2012.

(51) Int. Cl. H01L 29/06

(52) U.S. Cl. CPC H01L 29/0688
USPC 257/618

(57) ABSTRACT

The present invention provides a semiconductor device which includes the following components. A substrate with a first conductivity type has a cell region and a peripheral region thereon, wherein the peripheral region surrounds the cell region. An epitaxial layer having the first conductivity type is disposed on the substrate. A first spiral-shaped region having a second conductivity type is embedded in the epitaxial layer within the peripheral region and encircles the cell region.

### CROSS REFERENCE TO RELATED APPLICATIONS

This application claims the benefit of U.S. provisional application No. 61/595,007, filed on Feb. 3, 2012.

### BACKGROUND OF THE INVENTION

1. Field of the Invention

This present invention relates generally to the field of semiconductor devices and, more particularly, to a semiconductor device with super junction structure.

2. Description of the Prior Art

A power device is a semiconductor device mainly used in power management; it is for instance, used in switching power supplies, for management of integrated circuits in the core or the peripheral region of computers, in backlight power supplies and in a electric motor controls. In general, power devices can be classified into three major types, such as insulated gate bipolar transistors (IGBT), metal-oxide-semiconductor field effect transistors (MOSFET) and bipolar junction transistors (BJT). Among those types, the MOSFET is the most widely used power device because of its energy saving properties and its ability to provide faster switch speed.

In one kind of MOSFET power devices, P-type layers and N-type layers are arranged alternatively in order to form several PN junctions inside the device. These PN junctions are disposed along a direction vertical to the main device surface. A device with multiple vertical PN junctions is often called a super junction power device. In order to obtain devices with a relatively high voltage sustaining ability, super junctions located in active regions and peripheral regions are often have different layouts; for example, P-type layers within the cell region are composed of several discrete cylindrical P-columns embedded in N-type layers, which are arranged in a honeycomb layout. In contrast, the P-type layers within the peripheral region are composed of discrete concentric P-columns encircling one another. A width of each P-Columns and a spacing between adjacent P-Columns in the peripheral region are often smaller than in the active region.

However, in this case, since the active region and the peripheral region have different superjunction layouts, processes for fabricating these layouts generally include more than one photolithographic process. In addition, a width of each P-Column and a spacing between adjacent P-Columns in the peripheral region also need to be better controlled, so as to obtain a desired charge-balance or charge-imbalance termination. As a result, these will increase the complexity and the cost of corresponding fabrication processes. In light of the above, there is still a need to provide a relatively economic and easy way for fabricating power devices with superjunctions that are capable of overcoming the shortcomings and deficiencies of the prior art.

### SUMMARY OF THE INVENTION

It is one objective of the invention to provide a semiconductor device in order to solve the above-mentioned problems.

According to one embodiment, a semiconductor device includes a substrate, an epitaxial layer and a first spiral-shaped region. The substrate has a first conductivity type and is defined with a cell region and a peripheral region thereon, wherein the peripheral region surrounds the cell region. The epitaxial layer having the first conductivity type is disposed on the substrate. And the first spiral-shaped region, which has a second conductivity type, is embedded in the epitaxial layer within the peripheral region and encircles the cell region.

The present invention provides at least a spiral-shaped region within the peripheral region such that several transistors within the cell region can be encircled by the spiral-shaped region. In this layout, the electric field intensity can be smoothly reduced and terminated at the outmost edge of the spiral-shaped region. In other words, the breakdown voltage is enhanced and the leakage current is reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic diagram illustrating a top view of a semiconductor device according to one preferred embodiment of the present invention;

FIG. 2 is a schematic diagram illustrating a cross-sectional view along a cutting line 2-2′ shown in FIG. 1; and

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale, and some dimensions are exaggerated in the figures for clarity of presentation. Additionally, terms such as “first conductivity type” and “second conductivity type” used in the following paragraph refer relatively to conductive types between different materials; for example, first and second conductivity types may be deemed as n-type and p-type respectively, and vice versa.

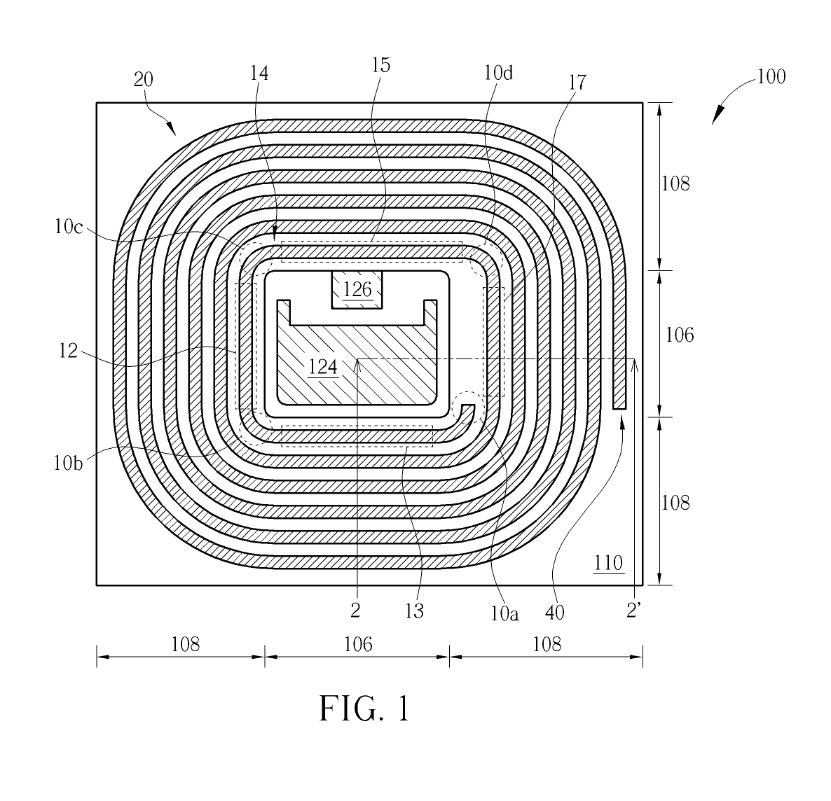

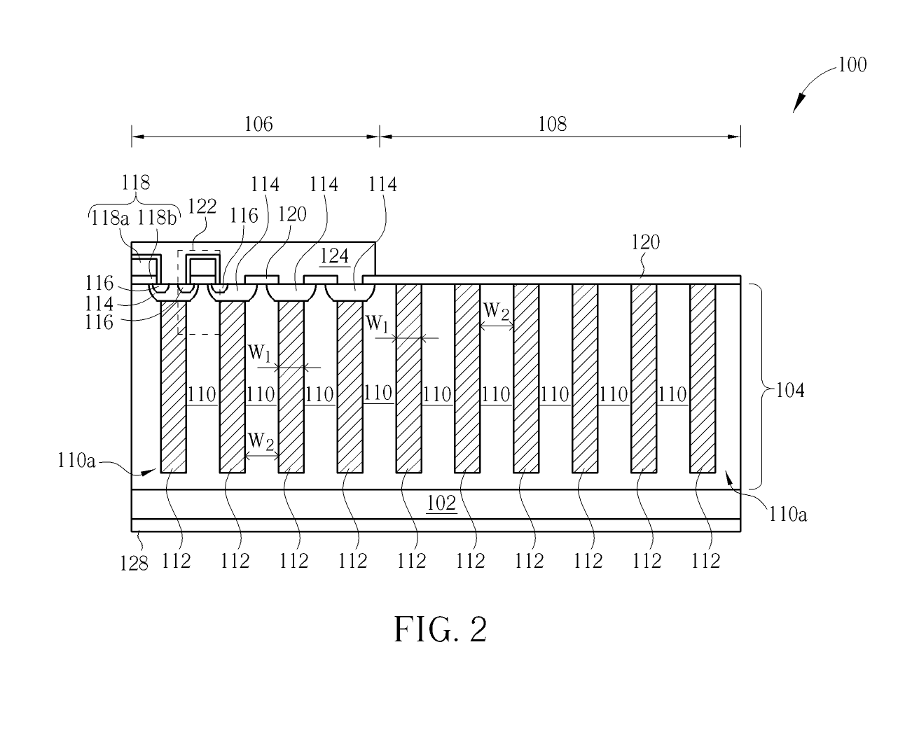

Please refer to FIG. 1 and FIG. 2. FIG. 1 is a schematic diagram illustrating a top view of a semiconductor device according to a preferred embodiment of the present invention. FIG. 2 is a schematic diagram illustrating a cross-sectional view along a cutting line 2-2′ in FIG. 1. As shown in FIG. 1 and FIG. 2, a semiconductor device 100 includes a substrate 102 having a first conductivity type such as an N-type. A cell region 106 and a peripheral region 108 surrounding the cell region 106 are defined on the substrate 102. The cell region 106 may include a source electrode 124 and a gate electrode 126, and is used to provide a switching function to transistor devices. In contrast, the peripheral region 108 is used to form a structure for protecting the transistor devices so as to prevent the semiconductor device 100 from reaching voltage breakdown.

The semiconductor device 100 further includes at least a spiral-shaped region 20 embedded in an epitaxial layer 110 within the peripheral region 108. The respective conductivity type of the spiral-shaped region 20 and the epitaxial layer 110 may be a second conductivity type, such as P-type, and the first conductivity type, respectively. In the cross-sectional diagram shown in FIG. 2, the P-type spiral-shaped region 20 alternates with the N-type epitaxial layer 110 so that the spiral-shaped region 20 along with the N-type epitaxial layer 110 may include a superjunction structure 104. In addition, the spiral-shaped region 20 has a continuous bands layout which encircles the cell region 106. In this embodiment, the spiral-shaped region 20 can be divided into several sub-spiral regions. For example, starting from the innermost sub-spiral region 14, one 90-degree curved portion 10a (encircled in dashed circle) of the innermost sub-spiral region 14 is located near the corner of the cell region 106. Since the innermost sub-spiral region 14 is a continuous band, the curved portion 10a will be connected to another portion of the innermost sub-spiral region 14, such as a linear portion 13 (encircled in dashed rectangle). For example, the curved portion 10a is connected to the linear portion 13 extending along the peripheral edge of the cell region 106 and is further connected to another 90-degree curved portion 10b located at the corner of the cell region 106. Similarly, this curved portion 10b may also be joined by another linear portion 12 (encircled in another dashed rectangle) and the rest may be deduced by analogy. That is to say, the innermost sub-spiral region 14 may include four linear portions 12, 13, 15 and 17 and four 90-degree curved portions 10a, 10b, 10c and 10d. Furthermore, the forth linear portion 17 can be connected to another sub-spiral region, such as a 90-degree curved portion encircling the innermost sub-spiral region 14. Consequently, several sub-spiral regions are connected sequentially and encircle one another. In addition, according to different requirements, the curved portion 10a may be either grounded or electrically floating. In the first case, the curved portion 10a can be electrically connected to the gate electrode 126 or to the source electrode 124 within the cell region 106. Since the gate electrode 126 or the source electrode 124 is grounded, this will cause the curved portion 10a to be grounded too. In another case, no current can directly flow from the spiral-shaped region 20 into the cell region 106, since the curved portion 10a near the cell region 106 ends within the epitaxial layer 110. Therefore, the curved portion 10a is electrically floating. In addition, the outmost end 40 of the spiral-shaped region 20 may also be embedded in the epitaxial layer 110 within the peripheral region 108. The outmost end 40 is preferably electrically floating, but is not limited thereto.

It should be noted that, in the above embodiments, since all these sub-spiral regions have the same widths W1 and spacings W2, the voltage sustaining ability within the peripheral region 108 can be enhanced by increasing the number of turns of the spiral-shaped region 20. One feature of the present invention is that, when a high voltage is applied to the semiconductor device 100, all the peripheral region 108 can be depleted quickly due to the existence of the continuous spiral-shaped region 20. As a result, a large-area depletion region is formed inside the peripheral region 108 and may be regarded as a resistor with relatively high resistance. In addition, another advantage of the present invention is that the electric field intensity within the peripheral region 108 is more uniform than that in a conventional semiconductor device where several discrete concentric bands are formed. As a consequence, leakage-current in the semiconductor device 100 will be prone to occur in the cell region 106 when the device 100 reaches breakdown voltage. All of these show that the reliability of the semiconductor device 100 can be improved.

In order to clearly detail the structure of the spiral-shaped region 20 within the epitaxial layer 110 of the above embodiments, please refer to FIG. 2 and briefly with FIG. 1. As shown in FIG. 2, the semiconductor device 100 of this embodiment includes a substrate 102 and a super junction structure 104. The substrate 102 has the first conductive type, and has a cell region 106 and a peripheral region 108 surrounding the cell region 106 defined thereon.

The super junction structure 104 is disposed on the substrate 102 within the cell region 106 and the peripheral region 108, which includes an epitaxial layer 110 having the first conductive type, and a plurality of semiconductor layers 112 having a second conductive type. The epitaxial layer 110 is disposed between any two of the adjacent semiconductor layers 112, so that each semiconductor layer 112 and the epitaxial layer 110 are disposed alternatively in sequence. As previously described, the semiconductor layers 112 within the peripheral region 106 has a spiral-shaped layout while the semiconductor layers 112 within the cell region 106 may have honeycomb or matrix layouts, but is not limited thereto. In the present invention, since the spacing W2 and width W1 of each semiconductor layer 112 within the peripheral region 108 may be the same as those within the cell region 106, each semiconductor layer 112 may have the same width W1, and the epitaxial layer disposed between any two of the adjacent semiconductor layers 112 may have the same width W2.

Furthermore, the N-type epitaxial layer 110 of this embodiment is disposed on the N-type substrate 102, and the N-type epitaxial layer 110 has a plurality of deep trenches 110a. Each P-type semiconductor layer 112 of this embodiment can be constituted of a P-type epitaxial layer, and each P-type semiconductor layer 112 is respectively disposed in and fills up each deep trench 110a so that a top surface of each P-type semiconductor layer 112 and a top surface of the N-type epitaxial layer 110 are on the same level. In this embodiment, no deep trench 110a is in contact with the N-type substrate 102, but the present invention is not limited to this. Each deep trench 110a of the present invention may also be etched further downward in order to be in contact with the N-type substrate 102, so that each P-type semiconductor layer 112 can be in contact with the N-type substrate 102. In other embodiments of the present invention, each P-type semiconductor layer 112 of the present invention also can be a P-type doped region in the N-type epitaxial layer 110, and the P-type doped regions are formed through a P-type ion implantation process and several epitaxy processes, but not limited to this.

In the cell region 106 there are a plurality of P-type doped body regions 114, a plurality of N-type doped source region 116, a plurality of gate structures and a dielectric layer 120. Each P-type doped body region 114 is disposed in each P-type semiconductor layer 112 in the cell region 106 and the corner region 108. Every two N-type doped source regions 116 are respectively disposed in each P-type doped body region 114. Each N-type doped source region 116 is used as a source of the transistor device. Each gate structure 118 is respectively disposed on the N-type epitaxial layer 110 between any two of the adjacent P-type semiconductor layers 112 in the cell region 106, and partially overlaps each P-type doped body region 114 and the corresponding N-type doped source region 116, such that each gate structure can be used as a gate of the transistor device, and each P-type doped body region 114 between each N-type doped source region 116 and N-type epitaxial layer 110 under each gate structure 118 can be used as a channel region of the transistor device. In addition, the N-type epitaxial layer 110 can be used as a drain of the transistor device, and each gate structure 118, each N-type doped source region 116, each P-type doped body region 114 and N-type epitaxial layer 110 can accordingly constitute one of the transistor devices 122. Each gate structure 118 is composed of a conductive layer 118a and an insulating layer 118b, which are sequentially disposed on the N-type epitaxial layer 110. The dielectric layer 120 covers the gate structures 118 and a part of the P-type semiconductor layers 112 and exposes the P-type doped body regions 114 disposed in each P-type semiconductor layer 112 between the cell region 106 and the corner region 108, the N-type doped source region 116 and a part of each conductive layer 118a. Moreover, the semiconductor device 100 further includes a source electrode 124, a gate metal layer 126 and a drain metal layer 128. The source electrode 124 is disposed on the dielectric layer 120, and is electrically connected to a part of the P-type semiconductor layers 112 in the cell region 106 and the corner region 108. The gate electrode 126 is disposed on the dielectric layer 120, which may surround the source electrode 124, and is electrically connected to each conductive layer 118a of each gate structure 118. The drain metal layer 128 is disposed under the N-type substrate 102 so as to be electrically connected to the N-type epitaxial layer 110.

As the above-mentioned description, the present invention provides the semiconductor device having at least a spiral-shaped region within the peripheral region. The spiral-shaped region along with the epitaxial layer comprises a superjunction structure which can provide a relatively smooth electric field intensity distribution within the peripheral region. In addition, since the voltage sustaining ability can be enhanced easily through increasing the number of turns of the spiral-shaped region, the complexity of the corresponding fabrication method can be reduced and a design requiring corresponding widths and spacings of a superjunction structure within the peripheral region is no longer a critical concern. Thus, the voltage bearing ability of the semiconductor device can be determined by the superjunction structure in the cell region, and will be limited by the superjunction structure within the peripheral region.

Although the disclosure has been illustrated by reference to specific embodiments, it will be apparent that the disclosure is not limited thereto as various changes and modifications may be made without departing from the scope of the present invention. References to “one embodiment’ or “an embodiment’ means that a particular feature, structure or characteristic described therein is included at least one embodiment. Thus, the appearances of the phrase “in one embodiment” or ‘in an embodiment” appearing in various places throughout the specification are not necessarily all referring to the same embodiment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate of a first conductivity type, the substrate having a cell region and a peripheral region thereon, wherein the peripheral region surrounds the cell region;
an epitaxial layer having the first conductivity type, wherein the epitaxial layer is disposed on the substrate; and
a first spiral-shaped region having a second conductivity type, wherein the first spiral-shaped region is embedded in the epitaxial layer within the peripheral region and encircles the cell region.

2. The semiconductor device according to claim 1, wherein the first spiral-shaped region comprises a plurality of linear portions and a plurality of 90-degree curved portions.

3. The semiconductor device according to claim 1, wherein the first spiral-shaped region comprises a plurality of sub-spiral regions encircling one another.

4. The semiconductor device according to claim 3, wherein each of the sub-spiral regions comprises four linear portions and four 90-degree curved portions.

5. The semiconductor device according to claim 4, wherein each of the sub-spiral regions have a same width.

6. The semiconductor device according to claim 4, wherein each spacing between two adjacent sub-spiral regions is substantially the same.

7. The semiconductor device according to claim 1, wherein the first spiral-shaped region is disposed along a peripheral edge of the cell region.

8. The semiconductor device according to claim 1, wherein one end of the first spiral-shaped region near the cell region is grounded.

9. The semiconductor device according to claim 8, wherein the end of the first spiral-shaped region is electrically connected to a conductive electrode in the cell region.

10. The semiconductor device according to claim 1, wherein one end of the first spiral-shaped region near the cell region is electrically floating.

11. The semiconductor device according to claim 1, wherein one end of the first spiral-shaped region away from the cell region is electrically floating.

12. The semiconductor device according to claim 1, wherein the first conductivity type is N-type and the second conductivity type is P-type.

13. The semiconductor device according to claim 1, wherein there is a smooth voltage drop in the first spiral-shaped region when a voltage is applied to the substrate.
